(19) United States
(12) Patent Application Publication
(10) Pub. No.: US 2009/0101204 A1
(43) Pub. Date: Apr. 23, 2009

(54) PHOTOVOLTAIC LAMINATED MODULE BACKSHEET, FILMS AND COATINGS FOR USE IN MODULE BACKSHEET, AND PROCESSES FOR MAKING THE SAME

(75) Inventors: Stanley Burton LEVY, Wilmington, DE (US); Josh COTTRELL, Rock City Falls, NY (US)

Correspondence Address: Mark D. Sweet;FINNEGAN, HENDERSON, FARABOW,, GARRETT & DUNNER, L.L.P., 901 New York Avenue, N.W., Washington, DC, 20001-4413, US

(73) Assignee: BioSolar, Inc.

(21) Appl. No.: 12/256,176

(22) Filed: Oct. 22, 2008

Related U.S. Application Data
(60) Provisional application No. 60/981,723, filed on Oct. 22, 2007.
(60) Provisional application No. 61/022,102, filed on Jan. 18, 2008.
(60) Provisional application No. 61/078,136, filed on Jul. 3, 2008.
(60) Provisional application No. 61/087,928, filed on Aug. 11, 2008.
(60) Provisional application No. 61/099,186, filed on Sep. 22, 2008.

(51) Int. Cl. H01L 31/00; B32B 37/00

(52) U.S. Cl. 136/256; 156/60; 156/242

(57) ABSTRACT

Improved photovoltaic module backsheets, and processes for making the same, are disclosed, including paper and polymer films for use in photovoltaic laminated modules. The present disclosure provides electrical insulation paper and one or more coatings or resin laminates having improved material properties, such as improved thermal and humidity performance, for use as backsheet materials in photovoltaic modules.

This application claims the benefit of U.S. Provisional Patent Application Nos. 60/981,723, filed Oct. 22, 2007; 61/022,102, filed Jan. 18, 2008; 61/078,136, filed Jul. 3, 2008; 61/087,928, filed Aug. 11, 2008; and 61/099,186, filed Sep. 22, 2008, which are herein incorporated by reference.

The invention relates generally to the field of photovoltaics, particularly to the use of paper and polymer films therein, and more specifically to an improved photovoltaic laminated module backsheet, and processes for making the photovoltaic laminated module backsheet.

Photovoltaic (“PV”) modules are large-area optoelectronic devices that convert solar radiation directly into electrical energy. PV modules are made by interconnecting individually formed and separate solar cells, e.g., multi-crystalline or mono-crystalline silicon solar cells, and then mechanically supporting and protecting the solar cells against environmental degradation by integrating the cells into a laminated PV module. The laminated modules generally comprise a rigid and transparent protective front panel or sheet, and a rear panel or sheet which is typically called a backsheet. Forming a sandwiched arrangement between the front panel and backsheet are the interconnected solar cells and an encapsulant which is transparent to solar radiation. The front panel and backsheet encapsulate the solar cell(s) and provide protection from environmental damage. Alternatively, a thin film material may be deposited on a rigid transparent layer, such as glass, and bonded to a backsheet with a transparent adhesive.

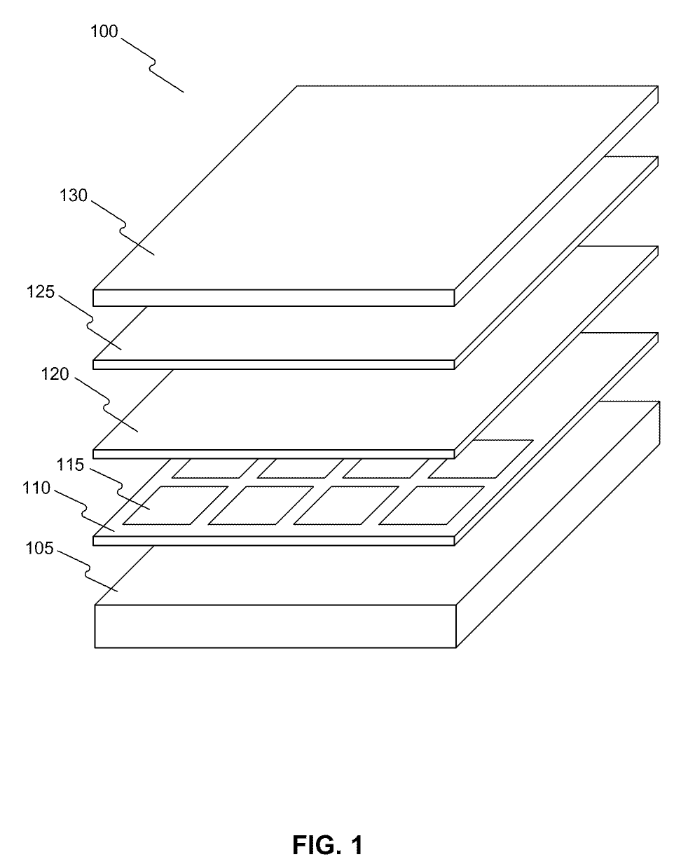

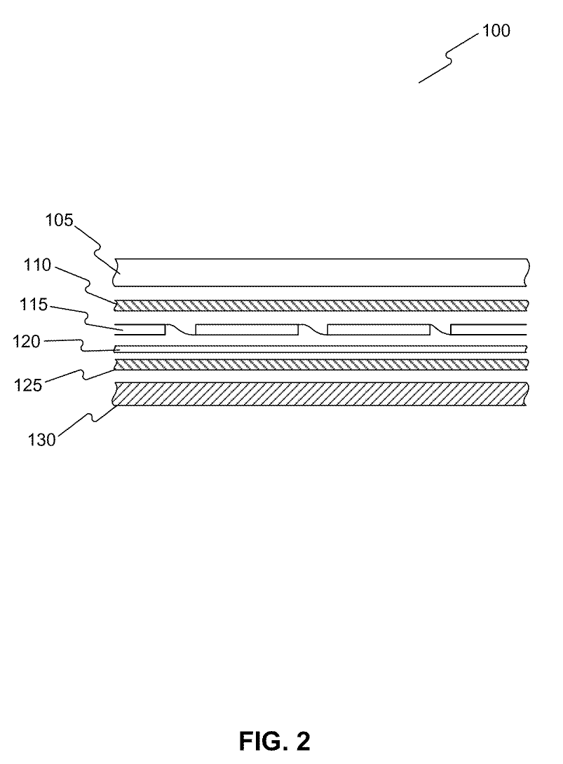

As shown in FIGS. 1 and 2, a laminated PV module 100 may be assembled in a sandwiched structure comprising a transparent front panel 105, (e.g., a front panel made of glass or a transparent polymer), a front layer of at least one sheet of encapsulant 110, an array of solar cells 115 interconnected by electrical conductors, a sheet of scrim 120 to facilitate gas removal during the lamination process, a back layer of at least one sheet of encapsulant 125, and a backsheet 130, followed by bonding these components together under heat and pressure using, e.g., a vacuum-type laminator. PV modules have been formed using a backsheet consisting of a thermoplastic polymer (e.g., a resin), glass, or some other material.

A known backsheet, for example, comprises a laminated structure of polyvinyl fluoride/polyester/ethylene vinyl acetate. Such a laminated structure, however, is not fully impervious to moisture, and as a consequence over time the power output and/or the useful life of PV modules made with this kind of backsheet material is reduced, e.g., due to electrical shorting resulting from absorbed moisture. Thus, the basic design and assembly process of PV modules can exhibit certain drawbacks.

A goal of the PV industry, however, is to have PV modules with an effective working life of decades. Thus, the materials used in constructing PV modules are selected with concern for providing adequate resistance to damage from impact and physical and thermal shock, maximizing the amount of usable solar radiation received by the cells, avoiding short-circuiting and electrical leakage, and minimizing degradation from such environmental factors as moisture, temperature, and ultra-violet sunlight-induced chemical reactions. A further concern of the PV industry is that the useful life goal of PV modules be attained at a commercially acceptable cost.

In addition to the PV industry goal of achieving PV modules with a long useful life at a commercially acceptable cost, the PV industry also seeks to compete with other forms of energy production, such as energy produced from petroleum and other fossil fuels. Thus, another primary goal of the PV industry is to generate “clean” electricity at a cost comparable or less than that of the petroleum industry, in addition to reducing reliance on the world's petroleum supply. However, the PV backsheets used in PV modules, such as those described above, are typically produced from petroleum-based chemicals, which, to a certain extent, defeats one of the goals of using solar energy.

There is an unmet need for non-petroleum-based chemicals for use in PV modules. Resins from renewable sources have been developed over the past several years as substitutes for conventional resins due to the dwindling supply of petroleum feedstocks, its increasing costs, and concerns about the environment. Some resins, for example, polylactic acid (PLA) resins, which are produced from corn or other renewable feedstock, have been considered by the present inventors and others for use in PV backsheets. These and other resins which may be produced from renewable or sustainable resources, however, have not been previously considered for use in PV backsheets—either because of relatively poor material properties or processing challenges.

For example, films extruded from PLA resins are brittle and do not typically have suitable material properties for use in PV backsheets. Extruded PLA resin brittleness has been at least partially overcome by the use of a biaxial orientation process following film extrusion from PLA resins. Improvements in PLA resin extrusion have been disclosed, for example, in U.S. Pat. No. 5,443,780. The biaxial orientation process, however, is complicated and capital intensive. Furthermore, film breaks frequently occur in the second (transverse) direction stretch, and gauge uniformity is difficult to control. The standard uniaxial (machine direction) process is much simpler and less capital intensive, but it does not solve the brittleness problem. In addition, films made using this process tend to have a very low tear strength in the machine direction.

In addition to improving material properties of films extruded from resins, such as improved ductility, impact resistance, and thermal performance, materials for use in PV backsheets will need to maintain their operating performance in real world conditions, including, for example, during continuous use as backsheets on PV modules operating in a multitude of climate conditions.

Therefore, consideration was given to materials made from renewable or sustainable resources, and combinations of those materials, for applicability in the preparation and processing of packaging, such as backsheets, for PV modules. In particular, there is a need to provide a useful laminate film, for use as a PV module backsheet, from a renewable or sustainable source.

In accordance with the systems and methods described below, there is provided a method of manufacturing a photovoltaic module, comprising: forming a photovoltaic backsheet by coating at least one side of an electrical insulation paper with an epoxy resin; and laminating the photovoltaic backsheet to at least one element chosen from a photovoltaic cell, an encapsulant, and a front panel.

In accordance with the systems and methods described below, there is also provided a photovoltaic module, comprising: a photovoltaic backsheet, the backsheet further comprising a laminate of an electrical insulation paper and an epoxy resin; and at least one element chosen from a photovoltaic cell, an encapsulant, and a front panel.

In accordance with the systems and methods described below, there is also provided a method of manufacturing a photovoltaic module, comprising: forming a photovoltaic backsheet by coating at least one side of an electrical insulation paper with at least one moisture resistant coating; and laminating the photovoltaic backsheet to at least one element chosen from a photovoltaic cell, an encapsulant, and a front panel.

In accordance with the systems and methods described below, there is provided a photovoltaic module, comprising: a photovoltaic backsheet, the backsheet further comprising a laminate of an electrical insulation paper and at least one moisture resistant coating; and at least one element chosen from a photovoltaic cell, an encapsulant, and a front panel.

In accordance with the systems and methods described below, there is also provided a method of manufacturing a photovoltaic module, comprising: forming a photovoltaic backsheet by coating at least one side of an electrical insulation paper with at least one layer of nylon-11; and laminating the photovoltaic backsheet to at least one element chosen from a photovoltaic cell, an encapsulant, and a front panel.

In accordance with the systems and methods described below, there is also provided a photovoltaic module, comprising: a photovoltaic backsheet, the backsheet further comprising a laminate of an electrical insulation paper and at least one layer of nylon-11; and at least one element chosen from a photovoltaic cell, an encapsulant, and a front panel.

In accordance with the systems and methods described below, there is provided a method of manufacturing a photovoltaic module, comprising: biaxially orienting and extruding at least one layer of a polylactic acid film; compression roll drawing the at least one layer of the polylactic acid film; forming a photovoltaic backsheet from the at least one layer of the polylactic acid film; and laminating the photovoltaic backsheet to at least one element chosen from a photovoltaic cell, an encapsulant, and a front panel.

In accordance with the systems and methods described below, there is also provided a photovoltaic module, comprising: a photovoltaic backsheet, the backsheet further comprising a laminate of at least one layer of a polylactic acid film; and at least one element chosen from a photovoltaic cell, an encapsulant, and a front panel.

Additional features and advantages of the invention will be set forth in part in the description that follows, being apparent from the description or learned by practice of embodiments of the invention. It is to be understood that both the foregoing general description and the following detailed description are exemplary and explanatory, and are intended to provide further explanation of the invention as claimed.

The accompanying drawings, which are incorporated in and constitute a part of this specification, illustrate embodiments of the invention and, together with the description, serve to explain the features, advantages, and principles of the invention. For illustration purposes, none of the following drawings are to scale. In the drawings:

FIG. 1 illustrates a perspective view of a PV module consistent with an embodiment of the present invention;

FIG. 2 illustrates a cross-sectional view of a PV module consistent with an embodiment of the present invention;

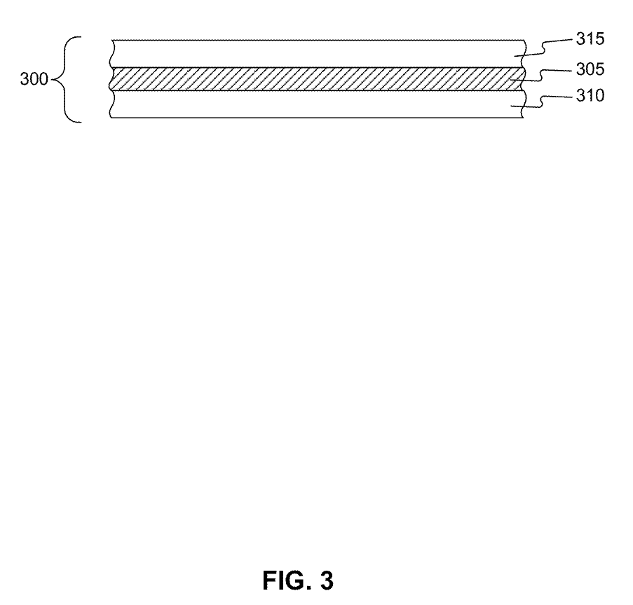

FIG. 3 illustrates a cross-sectional view of a PV backsheet consistent with an embodiment of the present invention;

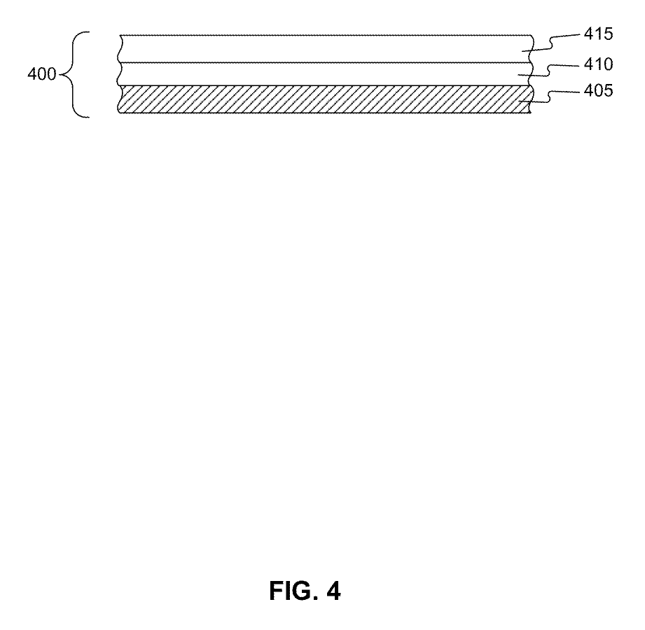

FIG. 4 illustrates a cross-sectional view of a PV backsheet consistent with an embodiment of the present invention;

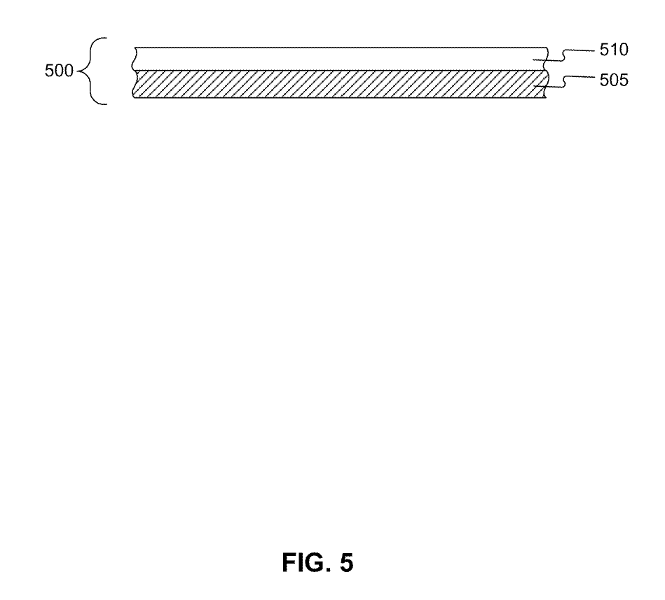

FIG. 5 illustrates a cross-sectional view of a PV backsheet consistent with an embodiment of the present invention;

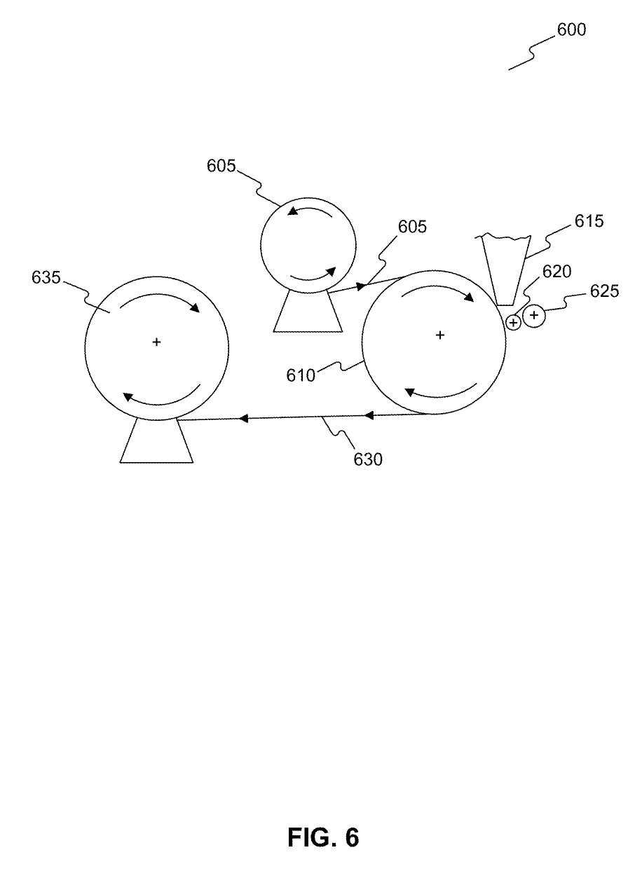

FIG. 6 is a schematic representation of an extrusion system for producing a PV backsheet consistent with an embodiment of the present invention;

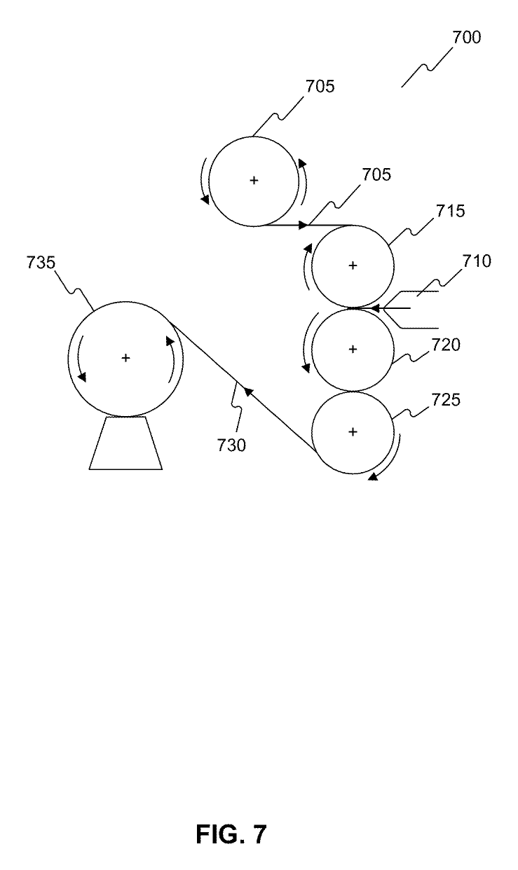

FIG. 7 is a schematic representation of an extrusion system for large-scale production of PV backsheets consistent with an embodiment of the present invention

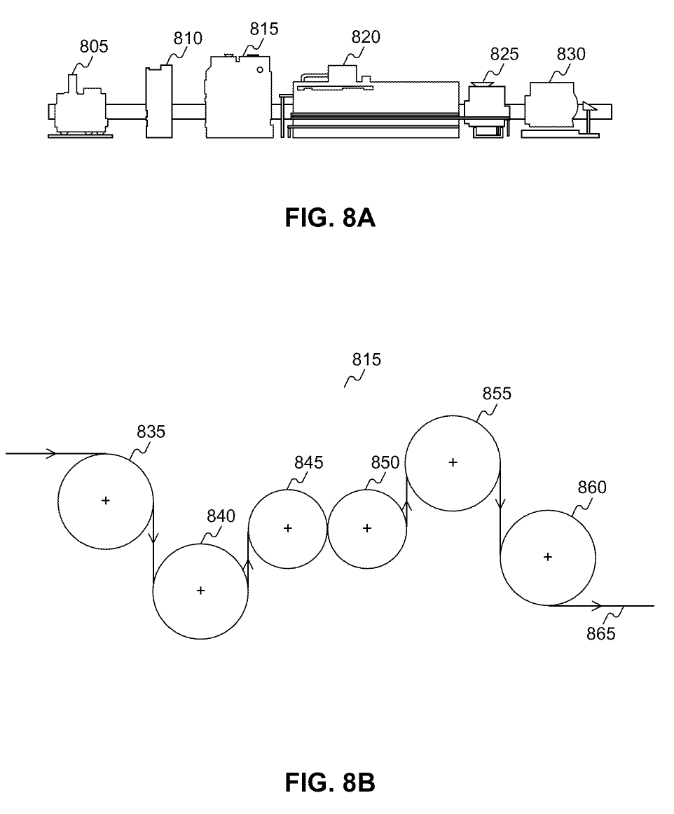

FIG. 8A is a schematic representation of a biaxial orientation line system for producing a PV backsheet consistent with an embodiment of the present invention;

FIG. 8B is a schematic representation of part of the extrusion system shown in FIG. 8B

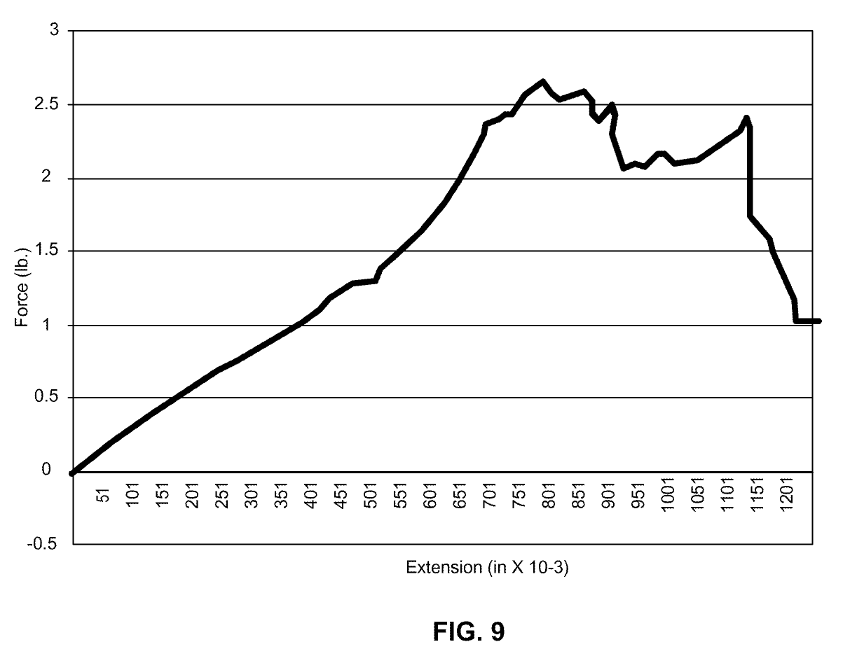

FIG. 9 is a graph illustrating a representative load curve measured from PV backsheets manufactured according to embodiments of the present invention; and

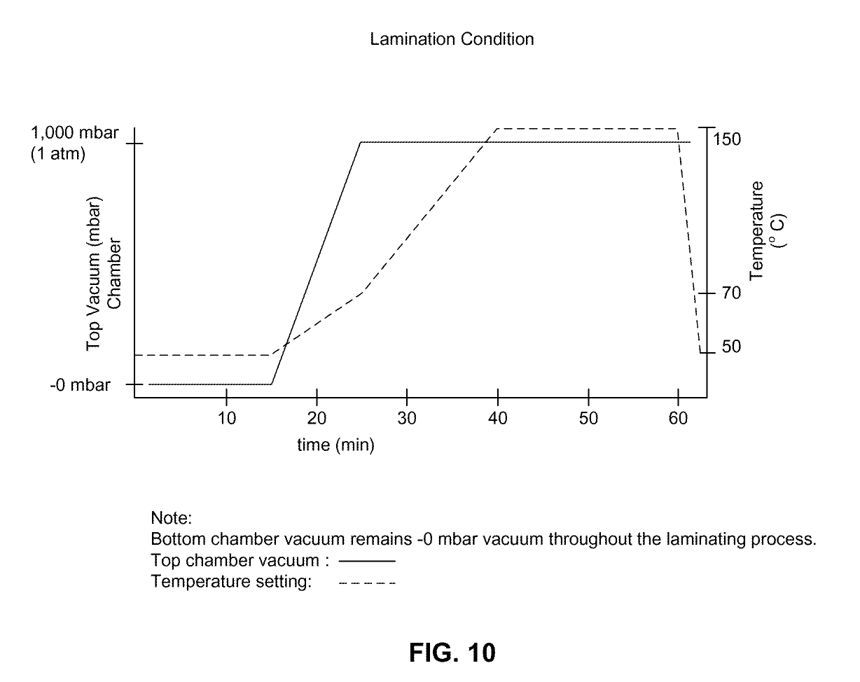

FIG. 10 is a graph illustrating a representative lamination process condition for laminating PV modules including PV backsheets manufactured according to embodiments of the present invention.

Reference will now be made in detail to embodiments of the present invention, examples of which are illustrated in the accompanying drawings. Wherever possible, the same or similar reference numbers will be used throughout the drawings to refer to the same or like parts.

The present disclosure provides for the production of laminate films, including films from a renewable and/or sustainable source, such as a film derived from a modified electrical insulation paper to which one or more coatings are applied. The present disclosure also provides systems and methods to improve the performance of these laminate films under heat and humidity environmental extremes, such as those presented during stringent UL testing, including, for example, the damp heat test and the humidity freeze test as outlined in UL 1703. Moreover, the present disclosure provides for laminate films suitable for packaging PV modules. For example, such films include films made from modified electrical insulation paper including one or more coatings, for backsheets and front glazings of PV modules, backsheets and front glazings for thin film PV modules, and films suitable for application of active PV materials by vacuum deposition, printing, or other means.

In embodiments consistent with the invention, materials from three sustainable resources have been targeted and developed for use as backsheets in PV modules: a cellulosic material made from cotton; a type of nylon made from castor beans; and polylactic acid (PLA) made from corn. Some of these films can be coated with various materials to lower the water vapor transmission rate (“WVTR”). PV modules produced using these backsheets were subjected to rigorous testing, including the damp heat test and the wet hypot test as outlined in UL 1703.

In accordance with an embodiment, there is disclosed a PV backsheet material manufactured from an electrical insulation paper. For example, such an electrical insulation paper can be a modified form of COPACO paper, with unmodified COPACO paper being commercially available from Cottrell Paper Company, Rock City Falls, N.Y.

In the past, electrical insulation papers, such as unmodified COPACO papers, were typically used in motors and transformers, such as power tools, garbage disposers, electrical contact barriers, and terminal boards, but not in PV applications. These types of paper films are used in many dielectric applications, and electrical insulation papers therefore have UL certification.

Most dielectric applications for electrical insulation papers, however, are moisture susceptible. In fact, experiments were conducted using known electrical insulation papers as backsheet materials for laminated PV modules, and the papers did not adequately protect the PV module from environmental damage, such as moisture damage. For example, known papers are hydrophilic, and thus fail to protect a laminated PV module from moisture when they are applied as a backsheet material.

Consistent with an embodiment, a modified electrical insulation paper was used as a backsheet material in the production of experimental laminated PV modules, and has shown excellent performance in UL damp heat testing. According to experimental results, laminated PV modules using the modified electrical insulation paper as a backsheet material satisfactorily survived the 1,000 hour UL 1703 damp heat test duration, without any measurable degradation in moisture resistance. Even though the manufacturing processes of these electrical insulation paper films are highly sophisticated, they are produced from an inexpensive precursor, e.g., cotton stock, and therefore are cost effective.

Consistent with an embodiment, the electrical insulation paper material can be made, for example, from scrap paper fabric cuttings (100% cotton stock), or high-grade new denim cuttings (e.g., 100% recycled cotton rags), and all foreign material such as metal and synthetics are removed. Alternatively, one or more other suitable materials and pulps may be used to make the electrical insulation paper, including, for example, cotton, cotton linter, softwood kraft, hardwood kraft, bamboo, jute, flax, kenaf, cannabis, abaca, sisal, linen, ramie, bagasse (sugar cane), rice, esparto, wheat, rye, sabai, or other manmade fibers (e.g., glass, ceramic, aramid, etc.). After the material passes inspection, it is size-reduced from about 1 square foot to about 1 square inch. It then undergoes bleaching and an additional contaminates removal process. The material stock is further size-reduced, washed, and fibrillated. The pulp undergoes an additional cleaning step and is diluted for entry into the film making machine. In this machine, the pulp is compressed and solidified in the final compression machine to form the film, and it undergoes an additional drying step. It is then calendered to increase the specific gravity from about 0.70 to about 1.25.

Moreover, the electrical insulation paper material may have a sizing added to the paper producing machine to help improve hydrophobic properties of the paper. Sizing may be achieved applying additives to the wet paper or to the dried paper. In certain embodiments, the sizing is added to the wet end of the paper producing machine. Consistent with an embodiment, a version of this modified COPACO electrical insulation paper material exhibits improved moisture resistance when used as a backsheet in a laminated PV module.

FIG. 3 illustrates a cross-sectional view of a PV backsheet 300 consistent with an embodiment of the present invention, including electrical insulation paper 305 and epoxy layers 310, 315. Consistent with an embodiment, after electrical insulation paper 305 is dried and calendared to improve its dielectric strength, it may be coated with epoxy layers 310, 315 to provide a moisture resistant barrier to both sides of the paper sheet. Experiments have indicated that applying an epoxy coating to one or more sides of the unmodified COPACO paper improved its moisture resistance in damp heat testing.

Moreover, experiments have successfully produced a full size working PV module using the modified COPACO electrical insulation paper as the backsheet, the paper having a chemical additive followed by an epoxy coating. The paper backsheet material exhibited excellent properties, including no wrinkling, excellent adhesion to the PV module, and satisfactory heat and moisture resistance to withstand environmental exposure as part of a laminated PV module. In addition, experimental results on smaller test PV modules made using the modified COPACO electrical insulation paper material as the backsheet indicate satisfactory performance during UL 1703 damp heat testing.

Consistent with an embodiment, modified electrical insulation papers can be made, for example, with a one-sided or two-sided epoxy coating applied over the paper and at least one internal chemical additive applied to the paper to improve moisture resistance, thereby enhancing the paper's ability to prevent moisture damage of PV modules on internal surfaces of laminated PV modules.

The chemical additive applied to the paper itself prior to coating with an epoxy resin may be, for example, Ciba® Raisafob® 9134C, which is commercially available from Ciba Specialty Chemicals, or any other suitable additive comprising alkyl ketene dimer (“AKD) as an active ingredient. Consistent with embodiments of the invention, other similar chemical additives may used, such as, for example, acrylic stearic anhydride (“ASA”) or alkenyl succinic anhydride. Moreover, the epoxy coating applied to the paper itself may be any suitable epoxy for improving the water resistance of the paper, and may be, for example, a proprietary epoxy coating which can be obtained from Bedford Materials Company.

Further experiments have indicated that applying a chemical additive to the paper itself, followed by applying the above-disclosed epoxy coating to one or more sides of the modified COPACO electrical insulation paper having the chemical additive, may improve its moisture resistance sufficiently enough to pass the tests of UL 1703. The grade of paper used in these experiments has a continuous duty temperature rating of about 105° C. The electrical insulation paper material used in these experiments has a relative temperature index (“RTI”) value of about 90° C. which is required for PV backsheet applications.

Consistent with an embodiment, the modified COPACO paper material disclosed herein is applicable for use as a PV backsheet material. Such PV backsheets may be manufactured by applying a chemical additive, such as Raisafob® 9134C, drying and calendaring, followed by application of an epoxy resin to one or both sides of the paper.

Consistent with another embodiment, it is also possible to combine a modified electrical insulation paper, such as a modified COPACO paper material, with one or more coatings to improve moisture resistance. That is, instead of applying the above-disclosed epoxy coating to the modified COPACO paper plus additive, the modified COPACO paper plus additive may be coated with one or more moisture resistant coatings, thereby eliminating the need for a separate epoxy coating on the modified COPACO paper.

Consistent with an embodiment, PV backsheets may be manufactured from modified electrical insulation papers having one or more coatings applied over the paper to improve moisture resistance, thereby enhancing the paper's ability to prevent moisture damage of PV modules. The coatings suitable for application on the modified electrical insulation papers may include coatings that have been used, for example, in the food-packaging industry. Such coatings may include Michelman® Coating X300; Michelman® Prime 2968 X1 (an ethylene acrylic acid based polymer), Michelman® Prime 4983R, Michelman® Vapor Coat® 500, Michelman® Vapor Coat® 501, and Michelman® Vapor Coat® 2200R.

Michelman® Vapor Coat® 500, for example, is a styrene butadiene rubber based polymer including a customized wax emulsion. It is a water-resistant coating with intermediate moisture barrier, and is a repulpable, printable and cold set gluable coating optimized for water resistance. It also offers moisture vapor transmission rate (“MVTR”) protection. Common uses of Michelman® Vapor Coat® 500 include packaging for produce and meats, or anywhere packaged goods require protection from water or moisture vapor. Michelman® Vapor Coat® 500 can also be used as a base coat for other barrier-enhancing Michelman coatings. Michelman® Vapor Coat® 500 has never before been used in PV backsheet applications.

In addition, Michelman® Vapor Coat® 2200R, for example, is an acrylic based polymer including a customized wax emulsion. It is a MVTR, water- and grease-resistant coating, which provides water and grease resistance and MVTR properties on kraft liner and other substrates. When applied over a base coat, such as over Michelman® Vapor Coat® 500, Michelman® Vapor Coat® 2200R is a repulpable coating and has been used as a replacement for some curtain coating applications, poly-laminated board, and plastic bags. Michelman® Vapor Coat® 2200R has never before been used in PV backsheet applications.

One or more of these coatings may be applied to a modified electrical insulation paper. For example, one or more of Michelman® Coating X300™ AF, Michelman® Prime 2968 X1, Michelman® Prime 4983R, Michelman® Vapor Coat® 500, Michelman® Vapor Coat® 501, and Michelman® Vapor Coat® 2200R may be applied to a modified electrical insulation paper to form a PV backsheet material. Preferably, two of Michelman® Coating X300™ AF, Michelman® Prime 2968 X1, Michelman® Prime 4983R, Michelman® Vapor Coat® 500, Michelman® Vapor Coat® 501, and Michelman® Vapor Coat® 2200R may be applied in a base coat/top coat arrangement on a modified electrical insulation paper to form a PV backsheet material.

FIG. 4 illustrates a cross-sectional view of a PV backsheet 400 consistent with an embodiment of the present invention, including electrical insulation paper 405, base coat 410, and top coat 415. Consistent with an embodiment, as shown in FIG. 4, Michelman® Vapor Coat® 500 may be applied as base coat 410 on modified electrical insulation paper 405, and Michelman® Vapor Coat® 2200R may be applied as top coat 415 on top of the Michelman® Vapor Coat® 500 coating. According to this embodiment, the electrical insulation paper material may be a modified COPACO electrical insulation paper material, having an uncoated, as-prepared thickness of approximately 6 mils. Also consistent with this embodiment, the modified COPACO electrical insulation paper material may be coated with a Michelman® Vapor Coat® 500 coating in an amount of approximately 2.5-5.0 wet pounds per 1,000 square feet. Also consistent with this embodiment, the modified COPACO electrical insulation paper material may be coated with a Michelman® Vapor Coat® 2200R coating in an amount of approximately 1.5-3.0 wet pounds per 1,000 square feet. Preferably, the modified COPACO electrical insulation paper material may be coated with a base coat of Michelman® Vapor Coat 500 coating in an amount of approximately 2.5-5.0 wet pounds per 1,000 square feet, followed by a top coat of Michelman® Vapor Coat® 2200R coating in an amount of approximately 1.5-3.0 wet pounds per 1,000 square feet, the top coat of Michelman® Vapor Coat® 2200R being coated on top of the Michelman® Vapor Coat® 500. Thus, the coating thickness may be approximately ¼ mil to approximately 1 mil thick, though this may vary from sample to sample.

Consistent with an embodiment, one or more of the above-disclosed coatings may be applied to a modified COPACO electrical insulation paper material by one of a rod coater, a Massey print roll coater, an air-knife coater, a blade coater, a size press coating, and cast coaters. Preferably, one or more of the above-disclosed coatings may be applied to a modified COPACO electrical insulation paper material by a rod coater.

Experiments have indicated that applying one or more of the above-disclosed coatings to a modified COPACO electrical insulation paper material, may improve its moisture resistance sufficiently enough to pass the tests of UL 1703. Specifically, a modified COPACO electrical insulation paper material, coated with a base coat of Michelman® Vapor Coat® 500 coating in an amount of approximately 2.5-5.0 wet pounds per 1,000 square feet, followed by a top coat of Michelman® Vapor Coat® 2200R coating in an amount of approximately 1.5-3.0 wet pounds per 1,000 square feet, was subjected to contact with water placed on top of the coated material for several days. In every experiment, the water placed on top of the coated material evaporated before any measurable amount of water absorbed into the coated material. In addition, further experiments being conducted as of the filing date of this application have demonstrated successful moisture and heat resistance for more than half-way through the duration of the damp heat test of UL 1703 for a test sample of a modified COPACO electrical insulation paper material, coated with a base coat of Michelman® Vapor Coat 500 coating in an amount of approximately 2.5-5.0 wet pounds per 1,000 square feet, followed by a top coat of Michelman® Vapor Coat® 2200R coating in an amount of approximately 1.5-3.0 wet pounds per 1,000 square feet.

FIG. 5 illustrates a cross-sectional view of a PV backsheet 500 consistent with an embodiment of the present invention, including electrical insulation paper 505, e.g., modified COPACO paper, and nylon-11 layer 510. Consistent with another embodiment, it is thus also possible to combine a modified electrical insulation paper, such as a modified COPACO paper material, with a nylon-11 resin. That is, as shown in FIG. 5, instead of applying the above-disclosed epoxy coating, or moisture resistant coatings, to the modified COPACO paper plus additive, modified COPACO paper 505 plus additive may be extrusion coated with nylon-11 510, thereby eliminating the need for a separate epoxy coating on the modified COPACO paper.

Nylon-11, produced from castor beans, is bio-sustainable, but not biodegradable. However, like most thermoplastics, it is recyclable. Thus, nylon-11 is the only known resin that can be manufactured from a sustainable resource (e.g., castor oil) and does not require petroleum in its production. It has improved moisture properties over the more common nylons, and has an RTI value of about 105° C. Both the moisture absorption and the WVTR are about five times lower than those properties of the more common nylon-6. The reason for this can be found in the relative structures of nylon-11 and nylon-6. The backbone of nylon-11 consists of ten methylene (hydrophobic) carbon chains and one carbonyl (hydrophilic) carbon chain. The backbone of nylon-6 consists of five methylene carbon chains and one carbonyl carbon chains. The ratio of hydrophobic carbon chains to hydrophilic carbon chains for nylon-11 is double that for nylon-6. In addition, nylon-11 has a continuous duty temperature rating of about 125° C.

Nylon-11 is currently manufactured by Arkema, Inc., headquartered in Philadelphia, Pa., and its product is marketed under the trademark Rilsan® PA₁₁ Rilsan® PA₁₁, is commonly used, for example, as an electrical insulator for underwater cables, and is available in several grades.

Consistent with an embodiment, Rilsan® PA₁₁ grade BESNO-TL may be used in a PV backsheet. However, other grades of Rilsan® PA₁₁ may also be used, for example, being modified with additives to improve thermal, mechanical, and/or UV performance. To date, however, no grade of nylon-11 resin has ever been used to make a PV backsheet. The inventors have worked with Arkema, Inc., and subsequently developed an improved resin grade of nylon-11 for use in a PV backsheet. The improved resin grade of nylon-11 comprises an additive package which includes both a UV and thermal stabilizer.

Nylon-11, such as, for example, Rilsan® PA₁₁ grade BESNO-TL, in combination with the electrical insulation paper described above, however, provides cost effective PV backsheet material with desirable material properties. Use of nylon-11 in combination with the electrical insulation paper described above would require only a comparably thin layer of nylon-11 (compared to the amount of nylon-11 which would be required in the absence of the electrically insulating paper). For example, nylon-11 film thicknesses for PV backsheet films using nylon-11 in combination with the electrical insulation paper are about 4 mils to about 12 mils. For example, and consistent with an embodiment, the electrical insulation paper may be about 5 mils to about 10 mils, with about 6 mils being typical. For example, and consistent with an embodiment, the nylon-11 may be about 2 mils to about 4 mils, with about 3 mils being typical. Therefore, consistent with an embodiment, the exposed side of the electrical insulation paper in a PV backsheet would be extrusion-coated with nylon-11 and the unexposed side would be protected by the encapsulated portions of the PV module. Specifically, Nylon-11, such as, for example, Rilsan® PA₁₁ grade BESNO-TL, may be used as a PV backsheet material, and such PV backsheets may be manufactured by one or more of adhesive bonding, extrusion, uniaxial (MD) orientation, and compression roll draw.

Consistent with an embodiment, a PV backsheet, such as the nylon-11/modified COPACO electrical insulation paper, may be produced by adhesive bonding the modified COPACO electrical insulation paper to the nylon-11, using either an activated or a pressure sensitive adhesive. For example, adhesives consistent with embodiments of the invention that may be used to bond nylon-11 can be solvent-based (such as, for example, polyester polyol two part crosslinking systems), water-based (such as, for example, polyurethane crosslinking systems), or solvent-less adhesives. Alternatively, vacuum deposition techniques may be used to apply nylon-11 to other materials, such as aluminum foil, aluminized polyethylene terephthalate (PET), polyvinyl fluoride (PVF) films, and polyvinylidene fluoride (PVDF) films.

Referring to FIG. 6, a PV backsheet, such as the nylon-11/modified COPACO electrical insulation paper, may be produced by extrusion coating the modified COPACO electrical insulation paper with nylon-11 in extrusion coater 600. Initial experiments on extrusion coating nylon-11 on modified COPACO electrical insulation paper were carried out at Randcastle Extrusion Systems, Inc., of Cedar Grove, N.J. Experiments produced several narrow rolls of a composite film of nylon-11/modified COPACO electrical insulation paper. In order to produce suitable composite films for use as PV backsheets, wound substrate, such as modified COPACO electrical insulation paper 605, may be unwound directly onto drum 610 while the molten polymer (not shown), such as molten nylon-11 impinges onto it from die 615. If the molten polymer was instead cast onto drum 610 and substrate 605 was applied to the molten polymer on drum 610, the molten polymer would prefer to stick to drum 610 rather than to substrate 605. Finally, the molten polymer is embedded into substrate 605 as a result of the extrusion process with the use of rubber pressure roll 620 and steel backing roll 625.

Several rolls of composite PV backsheet material, such as the nylon-11/modified COPACO electrical insulation paper, were produced by extrusion coating the modified COPACO electrical insulation paper with nylon-11 as described above and shown in FIG. 6. The composite PV backsheet material was subsequently used as backsheets for PV modules. The experimental PV modules were laminated (as described below with respect to FIG. 10) at SBM Solar. These experimental modules exhibited suitable adhesion and did not exhibit any wrinkling of the backsheet material. The experimental PV modules were a single solar cell construction, without framing and without junction boxes. I-V curves were run on several of the experimental modules, and they were put in the aging oven for the 1,000 hour damp heat test.

In addition, two experimental PV modules were prepared which included framing and a junction box. These PV modules were subject to the UL 1703 Wet Insulation-Resistance Test (i.e., the wet hypot test), which is a test of the resistance between electrically-shorted PV module output terminals and a specific water solution. To pass the tests of UL 1703, the measured resistance must be not less than 40 mega-ohms per square meter, or 400 mega-ohms for the PV module, whichever is greater, at 500 volts DC. That is, experiments on the nylon-11/modified COPACO electrical insulation paper, produced by extrusion coating the modified COPACO electrical insulation paper with nylon-11 as described above and shown in FIG. 6, have demonstrated moisture resistance sufficient to pass the tests of UL 1703. Specifically, a test module comprising about 6 mils modified COPACO electrical insulation paper and about 3 mils nylon-11 achieved 500 mega-ohms at 500 volts DC.

Referring to FIG. 7, a PV backsheet, such as the nylon-11/modified COPACO electrical insulation paper, may be produced by extrusion coating the modified COPACO electrical insulation paper with nylon-11 in extrusion coater 700. Actual production-scale experiments on extrusion coating nylon-11 on modified COPACO electrical insulation paper were carried out on a system configuration shown in FIG. 7. Although the extrusion system shown in FIG. 6 demonstrates the principle of PV backsheet composite production, large scale manufacture of PV backsheet composites may be accomplished with the system shown in FIG. 7. The configuration shown in FIG. 7 uses horizontal die 710, to impinge a molten polymer on substrate 705, in combination with a three roll casting system comprising roll 715, roll 720, and roll 725.

As shown in FIG. 7, each roll 715, roll 720, and roll 725 in the stack is independently temperature-controlled for improved processing control. Substrate 705 has a longer dwell time on roll 715 of the three roll stack for a more uniform temperature profile. Rolls 715 and 720 have significant mass, e.g., up to about 2,000 lbs., and a relatively large diameter, e.g., up to about 40 inches outside diameter. Thus, according to the system shown in FIG. 7, a very high compression force can be applied to help the molten polymer (not shown) wick into substrate 705 with a minimum of roll deflection over the width of roll 715, roll 720, and roll 725. Roll 715, roll 720, and roll 725 may be about 50 inches to about 60 inches wide. In addition, the speed of roll 725 can be varied independently of roll 715 and roll 720 to improve the flatness of the extruded composite PV backsheet material. The extruded product 730 may then be wound up on drum 735.

Still referring to FIG. 7, large scale extrusion coating systems, such as that shown in FIG. 7, are usually equipped with surface treating equipment, such as a corona discharge treater. Treating of substrate 705 with, for example, a corona discharge, increases its surface energy which, in turn improves the bond strength between the molten polymer and substrate 705. Moreover, substrate 705 can be embossed before coating, which significantly increases the bonding surface area of substrate 705 relative to its comparable pre-embossed flat surface area. For example, embossing may take place between heated roll steps, thereby roughening the surface of substrate 705 to provide increased bonding area. This also significantly increases bond strength

Consistent with another embodiment, there is disclosed a PV backsheet material manufactured from PLA films. That is, instead of using the above-disclosed epoxy coating, or moisture resistant coatings, on modified COPACO paper plus an additive, the modified COPACO paper plus an additive extrusion coated with nylon-11, PLA alone may be used as a PV backsheet material. Specifically, improvements have been made in PLA films and their manufacture, such as improvements in the ductility, impact resistance, and thermal performance of PLA films while decreasing brittleness, all accomplished by simpler means than using the existing technology. That is, PLA films have been produced that are suitable for PV backsheets and packaging of PV modules, including films for backsheets and front glazings of PV modules, backsheets and front glazings for thin film PV modules, and films suitable for application of active PV materials by vacuum deposition, printing, or other means.

PLA has generated recent interest because it is produced from a sustainable resource (i.e., corn), and is biodegradable. It is relatively inexpensive and it is cost competitive with polyethylene and polyester-type resins for single use applications, such as department store and supermarket bags, food and drink containers, and disposable tableware. Although many biodegradable resins are being discussed in the engineering community, PLA is the only known biodegradable resin which is readily available.

Like nylon-11, described above, PLA resin may be extruded into a film. However, PLA films alone generally tend to be brittle. Brittleness of PLA films can be solved by either controlling the extruded PLA film orientation or by using additives to the PLA. Orientation preserves the transparency of the PLA film, however, additives do not. Experiments have produced a biaxially oriented and extruded film from PLA resin on a large scale, for example, 60 inch wide films, at the Marshall & Williams Biaxial Orientation Laboratory of Parkinson Technologies, Inc., in Woonsocket, R.I. FIG. 8A shows a schematic of a biaxial orientation line used for extruding PLA films consistent with an embodiment of the invention. The biaxial orientation line shown in FIG. 8A consists of six main sections: extrusion & casting systems 805, beta gauge 810, machine direction (uniaxial) orientation/compression roll draw (“MDO/CRD”) system 815, TDO/oven system 820, surface treatment/beta gauge systems 825, and a turret winder 830. FIG. 8B shows the components of MDO/CRD system 815 in FIG. 8A, including first preheating roll 835, second preheating roll 840, slow draw roll 845, fast draw roll 850, heat set and cooling roll 855, cooling roll 860, followed by winding of extruded film 865.

PLA films produced using the system shown in FIGS. 8A and 8B were optically transparent and sufficiently tough for use as PV backsheets, and PV backsheets may be formed from at least one layer of PLA film. MDO/CRD system 815, shown in FIG. 8B, overcame the brittleness problems in extruded PLA films. Specifically, in MDO/CRD system 815, the gap between slow draw roll 845 and fast draw roll 850 is larger than the thickness of the input film. In addition, the application of a compressive force to the input film during stretching, imparts some degree of orientation perpendicular to the plane of the input film. This process yields an extruded film with sufficient elongation to be used in a PV backsheet, thereby ensuring that the input film is heat stabilized while preserving its gauge uniformity. Alternatively, at least one layer of the PLA film for use in a PV backsheet may be calendered.

### EXPERIMENTAL EXAMPLES

### Experimental Example 1

PLA 4042D resin (obtained from NatureWorks) was extruded and oriented into 8 mil thick film using a 2½″ 30:1 single screw extruder, a 24″ die, and MD oriented using a short gap stretching process. (While PLA 4042D resin was used in this experiment, PLA 4032D resin may also be used.) The extruder and die zones were set to yield a melt temperature of 425° F. The screw speed was 60 rpm, and the cast thickness was 25 mils. The casting roll temperature was 100° F. The two MD orienter preheat rolls were 141° F. and 143° F. respectively, and the cooling roll was as 101° F. The gap between the slow and fast draw rolls was set to 100 mils. The slow draw roll speed was about 11.2 feet/minute and the fast draw roll speed was about 33.9 feet/minute which yielded about an 8 mil film. The extruded PLA film was placed on a flat concrete floor, after which a 2 inch diameter steel ball was dropped onto the PLA film from a height of approximately four feet. The brittle PLA film shattered.

### Experimental Example 2

PLA 4042D (obtained from NatureWorks) was extruded and MD oriented according to the conditions as shown for Example 1, except the MD orientation was accomplished by compression roll draw (CRD) rather than short gap stretch. The only change was in the spacing of the slow and fast stretch rolls. In this example, the spacing was set to 7 mils. The extruded PLA film was placed on a flat concrete floor, after which a 2 inch diameter steel ball was dropped onto the PLA film from a height of approximately four feet. The PLA film did not shatter.

Also consistent with an embodiment, modified PLA films can be made, for example, with one or more chemical additives to reduce brittleness of extruded PLA films. Experiments to reduce brittleness of extruded PLA films were performed by applying additives to PLA resins. In particular, the inventors worked with Standridge of Social Circle, Ga. to develop an additive package containing an anti blocking agent, a filler, and a polymer chain extender to compound into the PLA resin. Preferably, the additive package comprises a PLA carrier resin, an antiblock/filler, a polymer chain extender, and 2-oxepanone. The resulting extruded PLA film with the additive package was of high quality, had dimensional stability, and significantly reduced brittleness. In particular, an experiment was performed by placing the extruded PLA film containing the additive package on a flat concrete floor, after which a 2 inch diameter steel ball was dropped onto the PLA film from a height of approximately four feet. The PLA film containing the additive package did not shatter. A comparable experiment was performed on a PLA film containing no additive package, and that PLA film shattered upon being impacted by the steel ball.

Experiments were conducted to produce several PV modules using an extruded PLA film containing the additive package. The PV modules were produced at SBM Solar of Concord, N.C. The PV modules produced used a glass/EVA/solar cell/EVA/backsheet sandwiched structure. The adhesion of the PLA backsheet film to the PV module was excellent, with no wrinkling or bubbling of the PLA backsheet after lamination of the PV module. Additional experiments are being conducted to determine what, if any, additives or other modifications can be made to the PLA film/additive package to enable it to pass the IEC defined damp heat test (1000 hours in an atmosphere of 85° C. and 85% relative humidity).

### Experimental Example 3

PLA 4032D resin (obtained from NatureWorks) was modified by Standridge Color Corporation by blending in an additive package containing an anti blocking agent, a filler, and a polymer chain extender. The PLA 4032D resin with the additive package has the Standridge code of 42346, and the additive comprises a PLA carrier resin, an antiblock/filler, a polymer chain extender, and 2-oxepanone. Alternatively, other additive packages containing one or more of an anti blocking agent, a filler, and a polymer chain extender may be used. This resin was extruded into a 10 mil film with conditions similar to Experimental Example 1 except that a 12 inch die was used and the screw speed was 15 rpm. The melt temperature was 412° F. The extruded PLA film was placed on a flat concrete floor, after which a 2 inch diameter steel ball was dropped onto the PLA film from a height of approximately four feet. The PLA film did not shatter. One of ordinary skill in the art would recognize that similar results could be obtained using different additive packages to PLA resins.

Consistent with embodiments of the invention, and depending upon the particular PV module and desired application, a modified PV backsheet may be required. In these cases, the PV backsheet material may be extrusion coated, laminated, or vacuum deposited onto other materials, such as aluminum foil, aluminized PET, PVF film, PVDF film, and others. Additionally, the PV backsheet material could be vacuum metalized using non-conductive metal oxides such as aluminum oxide or oxides of silicon.

PV backsheets produced according to embodiments of the present invention were subjected to several performance tests to determine their suitability for real-world usage conditions. In particular, the PV backsheets were subjected to damp heat testing, partial discharge testing, wet insulation resistance test (UL 1703), and the bond strength test.

The damp heat test of UL 1703 is one of the most stringent tests included in the IEC series of PV module qualification tests, which, as mentioned earlier, consists of 1,000 hours of exposure to 85° C. and 85% relative humidity. As of the filing date of this application, PV modules produced from PV backsheets according to embodiments of the present invention have survived testing in the damp heat oven for about 250 hours, and exhibit no evidence of corrosion or adhesion failure.

The partial discharge test is a measure of PV backsheet dielectric strength on the PV backsheet itself, not on the entire PV module. Measurements were made at Arizona State University on PV backsheets produced according to embodiments of the present invention. As of the filing date of this application, PV backsheets manufactured according to embodiments of the present invention have exhibited dielectric strength before dielectric breakdown averaging about 700 volts, which exceeds the partial discharge test requirement of 600 volts. It is expected that the requirement will be increase to 1,000 volts. Consistent with embodiments of the present invention, this more stringent requirement can be satisfied by increasing the thickness of the PV backsheet.

The wet insulation resistance test (UL 1703), more commonly known as the wet hypot test, is a current leakage test performed on a PV module which has been immersed in a water surfactant solution for two minutes. The electrical resistance is measured between the electrically shorted leads of the PV module and the solution at 500 volts. The electrical resistance must be greater than 400 mega-ohms. This test is particularly stringent for PV backsheet materials. As of the filing date of this application, PV backsheets manufactured according to embodiments of the present invention have exhibited electrical resistance of 500 mega-ohms.

The bond strength test involves a test of the adhesion between the PV backsheet and the encapsulating EVA adhesive in the PV module. For example, ASTM Standard D-3807, “Standard Test Method for Strength Properties of Adhesives in Cleavage Peel by Tension Loading,” which is more commonly referred to as the “peel test,” is a good measure of the adhesion between the PV backsheet and the encapsulating EVA adhesive in the PV module. Laminated PV modules, produced from PV backsheets manufactured according to embodiments of the present invention, were prepared in the following configuration: backsheet/EVA encapsulant/backsheet, leaving enough unbounded PV backsheet to be inserted into the jaws of an Instron tester. A typical load curve from PV backsheets manufactured consistent with embodiments of the invention, particularly using a modified COPACO electrical insulation paper, is shown in FIG. 9. One of ordinary skill in the art will recognize that the failure mode illustrated in FIG. 9 is cohesive, rather than adhesive. That is, the bond strength of the PV backsheet film to the EVA encapsulant is greater than the interlayer strength of PV backsheet film. During experimental testing, the backsheet itself fractured before the bond between the backsheet film and the rest of the module.

Finally, referring to FIG. 10, and consistent with embodiments of the present invention, processing chamber vacuum and temperature are illustrated as a function of time for laminating PV backsheet materials (including, for example, any of the materials described herein) to an active PV module. As shown in FIG. 10, the above-disclosed PV backsheet materials can be placed in contact with a solar cell and held at approximately 50° C. for approximately 15 minutes, after which the temperature can be increased at a suitable rate to approximately 150° C. over approximately 25 minutes. Thereafter, the temperature may be held at approximately 150° C. for approximately 20 minutes. During the ramp and hold times, out gassing of the resin material in laminating module can occur, which is indicated in FIG. 10 by the corresponding decrease in top chamber vacuum from almost zero mbar to approximately 1,000 mbar (1 atm) over a period of approximately 5 minutes, after which the top chamber can be maintained at 1,000 mbar (1 atm) for the duration of the laminate processing. For example, the processing shown in FIG. 10 may be performed on a P.Energy L 150A automatic PV module laminator, available from P.Energy. Alternatively, the processing may be performed on a clamshell type laminator, such as a SPI-LAMINATOR, available from Spire Solar Corp.

It will be apparent to those skilled in the art that various modifications and variations can be made in the disclosed systems and methods without departing from the scope or spirit of the invention. Other embodiments of the invention will be apparent to those skilled in the art from consideration of the specification and practice of the invention disclosed herein. It is intended that the specification and examples be considered exemplary only, with a true scope and spirit of the invention being indicated by the following claims.

What is claimed is:

1. A method of manufacturing a photovoltaic module, comprising:
forming a photovoltaic backsheet by coating at least one side of an electrical insulation paper with an epoxy resin; and
laminating the photovoltaic backsheet to at least one element chosen from a photovoltaic cell, an encapsulant, and a front panel.

2. The method according to claim 1, wherein the forming further comprises applying at least one chemical additive to the electrical insulation paper before the coating.

3. The method according to claim 2, further comprising drying and calendering the electrical insulation paper having the at least one chemical additive.

4. The method according to claim 2, wherein the at least one chemical additive comprises an alkyl ketene dimer, an acrylic stearic anhydride, or an alkenyl succinic anhydride.

5. The method according to claim 1, wherein the electrical insulation paper has a continuous duty temperature rating of at least about 105° C. and a relative temperature index of about 90° C.

6. The method according to claim 2, wherein the at least one chemical additive increases the moisture resistance of the electrical insulation paper.

7. A photovoltaic module, comprising:
a photovoltaic backsheet, the backsheet further comprising a laminate of an electrical insulation paper and an epoxy resin; and
at least one element chosen from a photovoltaic cell, an encapsulant, and a front panel.

8. The module according to claim 7, wherein the electrical insulation paper comprises at least one chemical additive to improve its moisture resistance.

9. The module according to claim 8, wherein the electrical insulation paper is dried and calendered.

10. The module according to claim 8, wherein the at least one chemical additive comprises an alkyl ketene dimer, an acrylic stearic anhydride, or an alkenyl succinic anhydride.

11. The module according to claim 7, wherein the electrical insulation paper has a continuous duty temperature rating of at least about 105° C. and a relative temperature index of about 90° C.

12. The module according to claim 8, wherein the electrical insulation paper comprising the at least one chemical additive is moisture resistant.

13. A method of manufacturing a photovoltaic module, comprising:
forming a photovoltaic backsheet by coating at least one side of an electrical insulation paper with at least one moisture resistant coating; and
laminating the photovoltaic backsheet to at least one element chosen from a photovoltaic cell, an encapsulant, and a front panel.

14. The method according to claim 13, wherein the at least one moisture resistant coating comprises a styrene butadiene rubber based polymer.

15. The method according to claim 13, wherein the at least one moisture resistant coating comprises an acrylic based polymer.

16. The method according to claim 13, wherein the at least one moisture resistant coating comprises a first coating of a styrene butadiene rubber based polymer and a second coating of an acrylic based polymer.

17. The method according to claim 13, wherein the at least one moisture resistant coating is applied an amount of approximately 1.5 to approximately 5.0 wet pounds per 1,000 square feet.

18. The method according to claim 13, wherein the coating comprises using at least article chosen from a rod coater, a Massey print roll coater, an air-knife coater, a blade coater, a size press coating, and a cast coater.

19. The method according to claim 13, wherein the forming further comprises applying at least one chemical additive to the electrical insulation paper before the coating.

20. The method according to claim 19, further comprising drying and calendering the electrical insulation paper having the at least one chemical additive.

21. The method according to claim 19, wherein the at least one chemical additive comprises an alkyl ketene dimer, an acrylic stearic anhydride, or an alkenyl succinic anhydride.

22. The method according to claim 13, wherein the electrical insulation paper has a continuous duty temperature rating of at least about 105° C. and a relative temperature index of about 90° C.

23. The method according to claim 19, wherein the at least one chemical additive increases the moisture resistance of the electrical insulation paper.

24. A photovoltaic module, comprising:
a photovoltaic backsheet, the backsheet further comprising a laminate of an electrical insulation paper and at least one moisture resistant coating; and
at least one element chosen from a photovoltaic cell, an encapsulant, and a front panel.

25. The module according to claim 24, wherein the at least one moisture resistant coating comprises a styrene butadiene rubber based polymer.

26. The module according to claim 24, wherein the at least one moisture resistant coating comprises an acrylic based polymer.

27. The module according to claim 24, wherein the at least one moisture resistant coating comprises a first coating of a styrene butadiene rubber based polymer and a second coating of an acrylic based polymer.

28. The module according to claim 24, wherein the at least one moisture resistant coating is applied an amount of approximately 1.5 to approximately 5.0 wet pounds per 1,000 square feet.

29. The module according to claim 24, wherein the electrical insulation paper comprises at least one chemical additive to improve its moisture resistance.

30. The module according to claim 24, wherein the electrical insulation paper is dried and calendered.

31. The module according to claim 24, wherein the at least one chemical additive comprises an alkyl ketene dimer, an acrylic stearic anhydride, or an alkenyl succinic anhydride.

32. The module according to claim 24, wherein the electrical insulation paper has a continuous duty temperature rating of at least about 105° C. and a relative temperature index of about 90° C.

33. The module according to claim 24, wherein the at least one chemical additive increases the moisture resistance of the electrical insulation paper.

34. A method of manufacturing a photovoltaic module, comprising:
forming a photovoltaic backsheet by coating at least one side of an electrical insulation paper with at least one layer of nylon-11; and
laminating the photovoltaic backsheet to at least one element chosen from a photovoltaic cell, an encapsulant, and a front panel.

35. The method according to claim 34, wherein the nylon-11 is grade BESNO-TL.

36. The method according to claim 34, wherein the forming further comprises applying at least one chemical additive to the electrical insulation paper before the coating.

37. The method according to claim 34, further comprising drying and calendering the electrical insulation paper having the at least one chemical additive.

38. The method according to claim 34, wherein the at least one chemical additive comprises an alkyl ketene dimer, an acrylic stearic anhydride, or an alkenyl succinic anhydride.

39. The method according to claim 34, wherein the electrical insulation paper has a continuous duty temperature rating of at least about 105° C. and a relative temperature index of about 90° C.

40. The method according to claim 34, wherein the nylon-11 has a continuous duty temperature rating of at least about 125° C. and a relative temperature index of about 105° C.

41. The method according to claim 34, wherein the at least one chemical additive increases the moisture resistance of the electrical insulation paper.

42. The method according to claim 34, wherein the nylon-11 is coated to a thickness of about 4 mils to about 12 mils.

43. The method according to claim 34, wherein the coating comprises extrusion coating the at least one layer of the nylon-11 onto the at least one side of the electrical insulation paper.

44. The method according to claim 34, wherein the at least one side of the electrical insulation paper is embossed prior to the extrusion coating.

45. The method according to claim 34, wherein the coating comprises adhesive bonding of the at least one layer of the nylon-11 onto the at least one side of the electrical insulation paper.

46. The method according to claim 45, wherein the adhesive bonding of the at least one layer of the nylon-11 onto the at least one side of the electrical insulation paper uses an activated adhesive or a pressure sensitive adhesive.

47. A photovoltaic module, comprising:
a photovoltaic backsheet, the backsheet further comprising a laminate of an electrical insulation paper and at least one layer of nylon-11; and
at least one element chosen from a photovoltaic cell, an encapsulant, and a front panel.

48. The module according to claim 47, wherein the nylon-11 is grade BESNO-TL.

49. The module according to claim 47, wherein the electrical insulation paper comprises at least one chemical additive to improve its moisture resistance.

50. The module according to claim 47, wherein the electrical insulation paper is dried and calendered.

51. The module according to claim 47, wherein the at least one chemical additive comprises an alkyl ketene dimer, an acrylic stearic anhydride, or an alkenyl succinic anhydride.

52. The module according to claim 47, wherein the electrical insulation paper has a continuous duty temperature rating of at least about 105° C. and a relative temperature index of about 90° C.

53. The module according to claim 47, wherein the at least one layer of the nylon-11 has a continuous duty temperature rating of at least about 125° C. and a relative temperature index of about 105° C.

54. The module according to claim 47, wherein the at least one chemical additive increases the moisture resistance of the electrical insulation paper.

55. The module according to claim 47, wherein the at least one layer of the nylon-11 has a thickness of about 4 mils to about 12 mils.

56. The module according to claim 47, wherein the at least one layer of the nylon-11 is extrusion coated onto the at least one side of the electrical insulation paper.

57. The module according to claim 56, wherein the at least one side of the electrical insulation paper is embossed prior to the extrusion coating.

58. The module according to claim 47, wherein the at least one layer of the nylon-11 is adhesive bonded onto the at least one side of the electrical insulation paper.

59. The module according to claim 58, wherein the adhesive bonded at least one layer of nylon-11 includes an activated adhesive or a pressure sensitive adhesive.

60. The module according to claim 7, wherein the backsheet has an electrical resistance of at least about 40 mega-ohms at about 500 volts, and the module has an electrical resistance of at least about 400 mega-ohms at about 500 volts.

61. The module according to claim 24, wherein the backsheet has an electrical resistance of at least about 40 mega-ohms at about 500 volts, and the module has an electrical resistance of at least about 400 mega-ohms at about 500 volts.

62. The module according to claim 47, wherein the backsheet has an electrical resistance of at least about 40 mega-ohms at about 500 volts, and the module has an electrical resistance of at least about 400 mega-ohms at about 500 volts.

63. The method according to claim 1, wherein the electrical insulation paper is formed from a pulp chosen from cotton, cotton linter, softwood kraft, hardwood kraft, bamboo, jute, flax, kenaf, cannabis, abaca, sisal, linen, ramie, bagasse, rice, esparto, wheat, rye, and sabai, or from a manmade fiber chosen from glass, ceramic, and aramid.

64. The method according to claim 13, wherein the electrical insulation paper is formed from a pulp chosen from cotton, cotton linter, softwood kraft, hardwood kraft, bamboo, jute, flax, kenaf, cannabis, abaca, sisal, linen, ramie, bagasse, rice, esparto, wheat, rye, and sabai, or from a manmade fiber chosen from glass, ceramic, and aramid.

65. The method according to claim 34, wherein the electrical insulation paper is formed from a pulp chosen from cotton, cotton linter, softwood kraft, hardwood kraft, bamboo, jute, flax, kenaf, cannabis, abaca, sisal, linen, ramie, bagasse, rice, esparto, wheat, rye, and sabai, or from a manmade fiber chosen from glass, ceramic, and aramid.

66. The module according to claim 7, wherein the electrical insulation paper is formed from a pulp chosen from cotton, cotton linter, softwood kraft, hardwood kraft, bamboo, jute, flax, kenaf, cannabis, abaca, sisal, linen, ramie, bagasse, rice, esparto, wheat, rye, and sabai, or from a manmade fiber chosen from glass, ceramic, and aramid.

67. The module according to claim 24, wherein the electrical insulation paper is formed from a pulp chosen from cotton, cotton linter, softwood kraft, hardwood kraft, bamboo, jute, flax, kenaf, cannabis, abaca, sisal, linen, ramie, bagasse, rice, esparto, wheat, rye, and sabai, or from a manmade fiber chosen from glass, ceramic, and aramid.

68. The module according to claim 47, wherein the electrical insulation paper is formed from a pulp chosen from cotton, cotton linter, softwood kraft, hardwood kraft, bamboo, jute, flax, kenaf, cannabis, abaca, sisal, linen, ramie, bagasse, rice, esparto, wheat, rye, and sabai, or from a manmade fiber chosen from glass, ceramic, and aramid.
